(19) United States
(12) Patent Application Publication
(10) Pub. No.: US 2013/0223021 A1
(43) Pub. Date: Aug. 29, 2013

(54) Method For Locating A Printed Circuit Board Within An Enclosure

(71) Applicant: Control Techniques Ltd, (US)

(72) Inventor: Jonathan Robert Holman, Shrewsbury (GB)

(73) Assignee: CONTROL TECHNIQUES LTD, Newtown (GB)

(21) Appl. No.: 13/780,867

(22) Filed: Feb. 28, 2013

(30) Foreign Application Priority Data
Feb. 28, 2012 (GB) 1203492.2

(51) Int. Cl. H05K 1/02; H05K 13/00; H05K 7/14

(52) U.S. Cl. CPC H05K 1/02; H05K 7/1417; H05K 13/0023
USPC 361/748; 174/535; 29/825

(57) ABSTRACT

An apparatus is provided comprising an enclosure for enclosing a printed circuit board (PCB). The PCB has a tab extending therefrom. The enclosure comprises first and second portions, one of which includes a recess arranged to receive the tab of the PCB.

### CROSS-REFERENCE TO RELATED APPLICATION

This application claims the benefit and priority of Great Britain Patent Application No. GB 1203492.2 filed Feb. 28, 2012. The entire disclosure of the above application is incorporated herein by reference.

### FIELD

The invention relates to methods of locating a printed circuit board (PCB) within an enclosure.

### BACKGROUND

It is known to secure a PCB within an enclosure for various applications, for example during the construction of a drive unit.

In known methods of locating a PCB within an enclosure, the PCB is mounted on supports extending from the enclosure. Part of the enclosure is removable to provide access to the interior of the enclosure. The supports extend from the back face of the enclosure into its interior. Each support receives a screw.

A PCB to be located in the enclosure has a number of mounting holes. Each mounting hole corresponds to one of the supports extending from the back face of the enclosure. To locate the PCB in the enclosure, the PCB is positioned in the enclosure such that the supports of the enclosure are aligned with the mounting holes of the PCB. A screw is then fastened through each of the mounting holes of the PCB to the supports of the enclosure, thereby locating the PCB in the enclosure. Additional components may be located into the enclosure as required, and the removable side of the enclosure is replaced.

Thus, in known methods, the PCB must be carefully positioned in the enclosure during assembly. Furthermore, the PCB must be fixed to the supports extending from the back face of the enclosure whilst the PCB is being positioned before the removable part of the enclosure is replaced to complete the assembly. Both of these steps add complexity to the assembly procedure, increasing the time taken to locate the PCB within the enclosure.

### SUMMARY

An invention is set out in the claims.

According to an aspect an apparatus is provided comprising an enclosure for enclosing a printed circuit board (PCB), the PCB having a tab extending therefrom. The enclosure comprises a first portion and a second portion, wherein one of the first and second portions includes a recess arranged to receive the tab of the PCB. The PCB may be located between the first and second portions of the enclosure when the apparatus is assembled with the PCB. The PCB may be secured within the enclosure due to the tab of the PCB being received within the recess in the first or second portion of the enclosure.

According to an aspect a printed circuit board (PCB) is provided wherein that PCB comprises a tab for locating the PCB within an enclosure, for example an enclosure having first and second portions one of which has a recess arranged to receive the tab of the PCB.

According to an aspect a method is provided for locating a printed circuit board (PCB) within an enclosure, wherein the PCB includes a tab extending therefrom. The enclosure comprises a first portion and a second portion wherein the first portion includes a recess arranged to receive the tab of the PCB. The method comprises locating the PCB with respect to the first portion such that the tab of the PCB is received into the recess and then securing the second portion of the enclosure to the first portion of the enclosure. The PCB may thus be located between the first and second portions of the enclosure. The second enclosure may also comprise a recess which assists in location of the PCB within the enclosure. For example, the tab of the PCB may be partly located in the recess of the first portion and partly located in the recess of the second portion of the enclosure.

### BRIEF DESCRIPTION OF THE DRAWINGS

Specific embodiments are described below by way of example only and with reference to the accompanying drawings, in which:

FIG. 1 shows a plan view of a first portion of an enclosure;

FIG. 2 shows a plan view of a PCB;

FIG. 3 shows a side view of the first portion of the enclosure, a second portion of the enclosure and the PCB before assembly; and

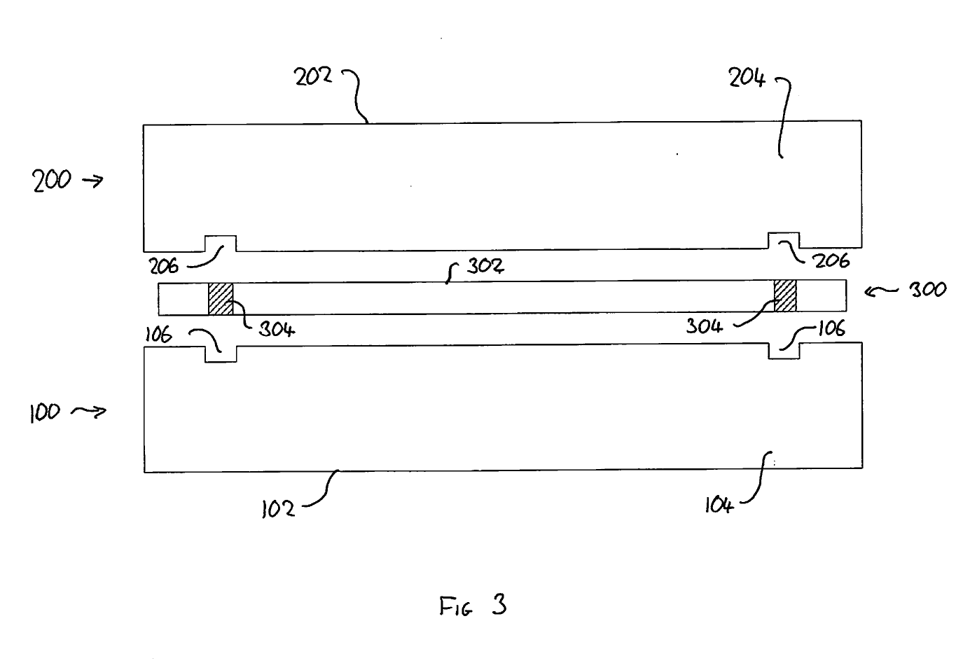

FIG. 4 shows a side view of the first and second portions of the enclosure and the PCB after assembly.

### OVERVIEW

A PCB is supported within an enclosure where space is at a premium. The enclosure is split into two portions to allow assembly. The first portion of the enclosure, the PCB and the second portion of the enclosure form a ‘sandwich’ when assembled with the PCB supported in the centre. No additional fixing means are required to support the PCB in the enclosure. To further support and locate the PCB within the enclosure, tabs protruding from the edge of the PCB are provided and located within cut-out portions provided in the walls of the first and second portions of the enclosure.

### DETAILED DESCRIPTION

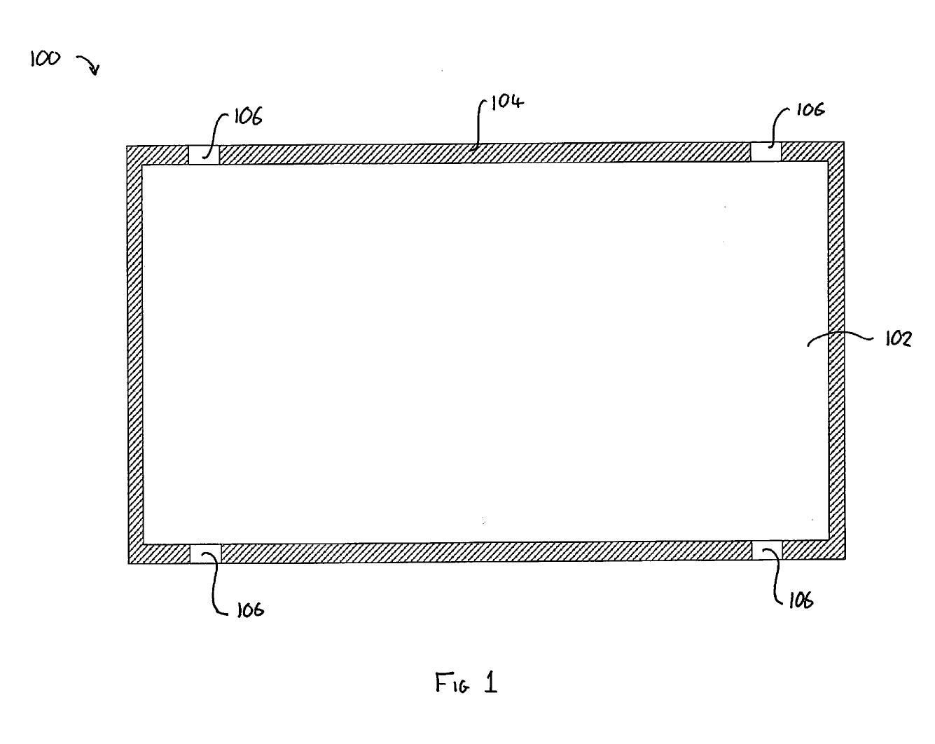

An enclosure comprises a first portion 100 and a second portion 200. As shown in FIG. 1, the first portion 100 comprises a back face 102 and a surrounding wall 104 extending in a substantially perpendicular direction from the back face 102 around its perimeter. The surrounding wall 104 has a thickness in the plane of the back face 102 of the first portion 100. The first portion 100 of the enclosure has cut-out portions 106 in the surrounding wall 104 distal to the back face 102. The cut-out portions 106 extend across the thickness of the surrounding wall 104, and have a depth perpendicular to the plane of the back face 102 of the first portion 100.

The second portion 200 is substantially identical to the first portion 100 and comprises a front face 202 and a surrounding wall 204 extending in a substantially perpendicular direction from the front face 202 around its perimeter. The surrounding wall 204 has a thickness in the plane of the front face 202 of the second portion 200. The second portion 200 of the enclosure has cut-out portions 206 in the surrounding wall 204 distal to the front face 202. The cut-out portions 206 extend across the thickness of the surrounding wall 204, and have a depth perpendicular to the plane of the front face 202 of the second portion 200.

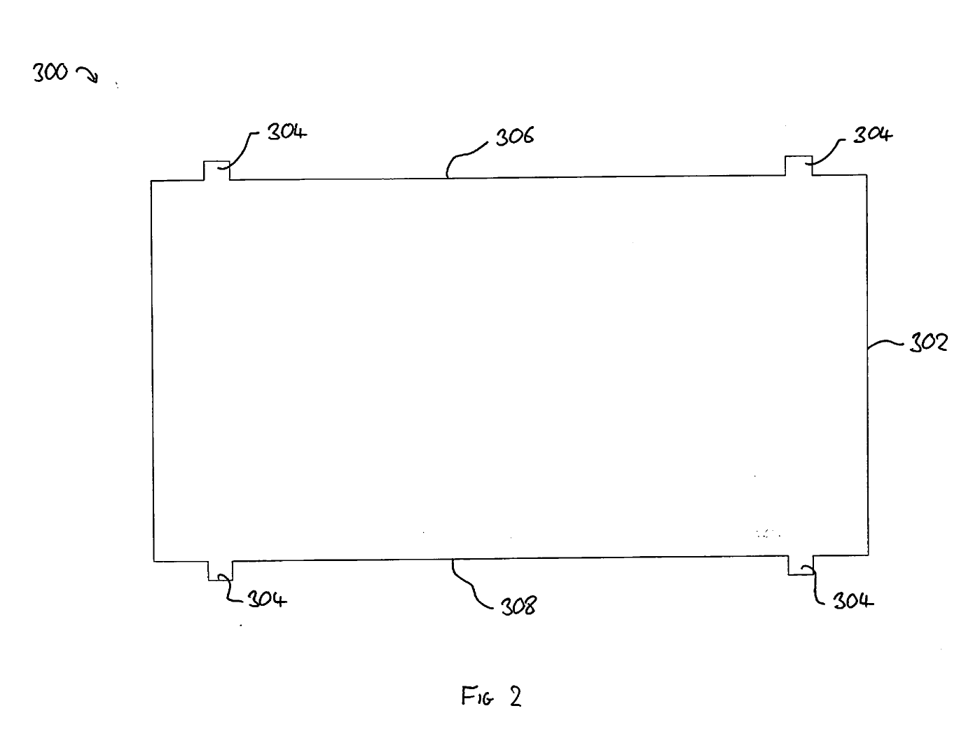

As shown in FIG. 2, a PCB 300 comprises a substantially planar surface 302 defined by a continuous edge. The edge of the PCB 300 includes a first side 306 and a second side 308 opposite thereto. The PCB 300 has tabs 304 extending from the first 306 and second 308 sides of the PCB 300 substantially co-planar with the planar surface 302. The tabs 304 have a height in a direction perpendicular to the plane of the planar surface 302. The height of each tab 304 substantially corresponds to the combined depths of a cut-out portion 106 in the first portion 100 and a cut-out portion 206 in the second portion 200.

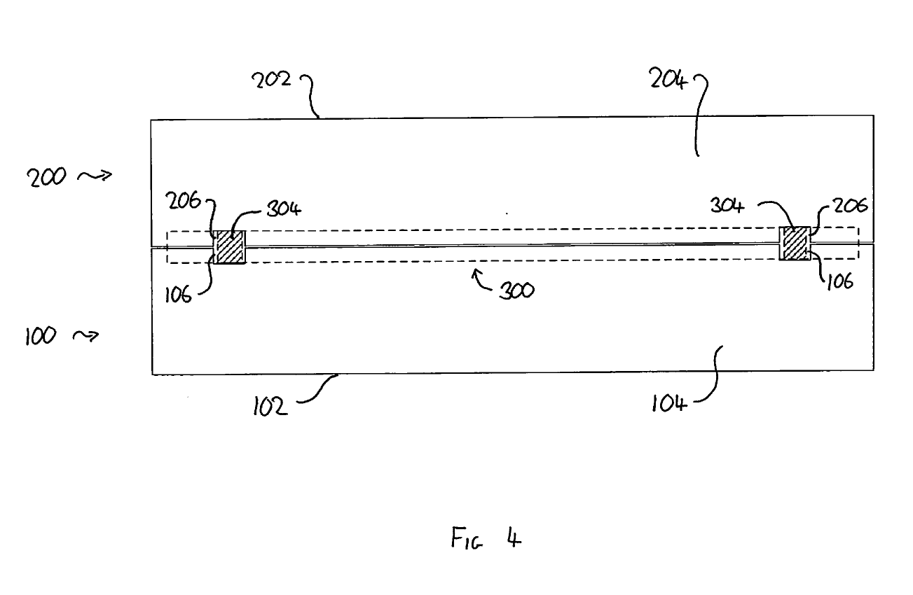

To locate the PCB 300 in the enclosure, the tabs 304 of the PCB 300 are located in the cut-out portions 106 of the first 100 portion of the enclosure. The second portion 200 of the enclosure is then placed over the PCB 300 and the first portion 100, such that the tabs 304 of the PCB 300 are received into the cut-out portions 206 of the second portion 200, thereby securing the PCB 300 within the enclosure as shown in FIG. 4. Because the PCB 300 is secured by the tabs 304 of the PCB 300, no additional means are required to locate the PCB 300 within the enclosure.

The assembly may be secured using any known method. For example, the first 100 and second 200 portions of the enclosure may be fixed together by a clip or with some other mechanical fastener.

Thus, the PCB 300 is sandwiched between the first and second portions of the enclosure and does not require any additional fixing. The tabs 304 of the PCB 300 and the cut-out portions 106 and 206 of the first 100 and second 200 portions of the enclosure serve both to position the PCB 300 in the enclosure and to secure the PCB 300 in the completed assembly. An electronic device is therefore provided that can be assembled quickly and easily.

Whilst a particular embodiment has been shown and described in detail herein, it is not intended to be limiting and variations are possible. In an alternative embodiment, the cut-out portions 106 and 206 may only partially extend across the thickness of the surrounding walls 104 and 204. In this embodiment, the tabs 304 of the PCB 300 are correspondingly smaller so that the PCB 300 is entirely enclosed when the enclosure is assembled.

Although the first 100 and second 200 portions of the enclosure are described above as being substantially identical, the first 100 and second 200 portions may differ. For example, the cut-out portions 106 of the first portion 100 may be have a depth suitable to accommodate the full height of the tabs 304, and the second portion 200 may have no cut-out portions 206, or vice versa. The first 100 and second 200 portions may also differ from one another in other aspects, for example in size and shape.

The PCB 300 may include any number of tabs 304. The tabs 304 may be of any shape or size, and tabs 304 on the first side 306 of the PCB 300 may be aligned with tabs 306 on the second side 308, or the tabs 304 on each side of the PCB 300 may be offset with respect to one another. The position, shape or size of tabs 304 may be chosen to correspond with the cut-out portions 106, 206 on the first 100 and second 200 portions of the enclosure so as to ensure correct orientation of the PCB 300 with respect to those first 100 and second 200 portions.

References to “first”, “second”, “back”, “side” and “front” herein are merely descriptive and refer to the orientation of the device as shown in the figures. They are not intended to be limiting.

The cut-out portions 106 and 206 referred to above are not necessarily formed by a cutting process, and may instead be referred to as, inter alia, recesses, holes, openings or indentations.

Thus a straightforward and efficient means for locating and fixing a PCB within an enclosure is provided. Because no screws are required in order to locate the PCB within the enclosure, the process of locating the PCB and assembling the enclosure is quicker, more straightforward and less susceptible to human error. Furthermore, the tabs on the PCB can help to ensure that the PCB is oriented properly with respect to the first and second portions of the enclosure.

The solution described herein can be used in any type of device in which a PCB must be sandwiched or otherwise located within an enclosure. The solution is scalable and can be used with any size or type of PCB. Furthermore, several PCB's can be located within the same enclosure or device using mating tabs and recesses such as the ones described herein. Thus a straightforward solution that is very useful in practice is provided.

1. An apparatus comprising an enclosure for enclosing a printed circuit board (PCB), the PCB having a tab extending therefrom,
the enclosure comprising a first portion and a second portion, wherein one of the first and second portions includes a recess arranged to receive the tab of the PCB.

2. The apparatus of claim 1, wherein the first and second portions each comprise a first face and a wall extending from the perimeter of the first face, wherein the recess is provided in a part of the wall distal to the first face.

3. The apparatus of claim 1 or claim 2, wherein, when the apparatus is assembled with a PCB, the PCB is secured in the enclosure by the tab of the PCB being received within the recess.

4. The apparatus of claim 1, wherein, when the apparatus is assembled with a PCB, the PCB is located between the first and second portions of the enclosure.

5. The apparatus of claim 1, wherein the first and second portions each comprise a recess.

6. A printed circuit board (PCB) comprising a tab for locating the PCB within an enclosure.

7. A method for locating a printed circuit board (PCB) within an enclosure, wherein the PCB includes a tab extending therefrom,
the enclosure comprising a first portion and a second portion, wherein the first portion includes a recess arranged to receive the tab of the PCB,
the method comprising locating the PCB with respect to the first portion such that the tab of the PCB is received into the recess, and
securing the second portion of the enclosure to the first portion of the enclosure.

8. The method of claim 7, wherein as a result of the step of securing the second portion of the enclosure to the first portion of the enclosure, the PCB is located between the first and second portions of the enclosure.

9. The method of claim 7, wherein the first and second portions each comprise a face and a wall extending from the respective face, wherein the recess is provided in a part of the respective wall, distal to the face.

10. The method of claim 7, wherein the first and second portions each comprise a recess, and wherein the step of securing the second portion of the enclosure to the first portion of the enclosure includes locating the tab of the PCB in the recess of the second portion of the enclosure.

11. (canceled)

12. The apparatus of claim 2, wherein, when the apparatus is assembled with a PCB, the PCB is secured in the enclosure by the tab of the PCB being received within the recess.

13. The apparatus of claim 2, wherein, when the apparatus is assembled with a PCB, the PCB is located between the first and second portions of the enclosure.

14. The apparatus of claim 3, wherein, when the apparatus is assembled with a PCB, the PCB is located between the first and second portions of the enclosure.

15. The apparatus of claim 12, wherein, when the apparatus is assembled with a PCB, the PCB is located between the first and second portions of the enclosure.

16. The apparatus of claim 2, wherein the first and second portions each comprise a recess.

17. The apparatus of claim 3, wherein the first and second portions each comprise a recess.

18. The apparatus of claim 12, wherein the first and second portions each comprise a recess.

19. The apparatus of claim 4, wherein the first and second portions each comprise a recess.

20. The apparatus of claim 13, wherein the first and second portions each comprise a recess.

21. The apparatus of claim 14, wherein the first and second portions each comprise a recess.
